(19) United States
(12) Patent Application Publication
(10) Pub. No.: US 2021/0278441 A1
(43) Pub. Date: Sep. 9, 2021

(54) IDENTIFYING ONE OR MORE ACQUISITIONS OF INTEREST USING VISUAL QUALIFICATION

(71) Applicant: Tektronix, Inc., Beaverton, OR (US)

(72) Inventors: Gary J. Waldo, Hillsboro, OR (US); Pierre Dupont, Verrières le Buisson (FR)

(73) Assignee: Tektronix, Inc., Beaverton, OR (US)

(21) Appl. No.: 17/191,059

(22) Filed: Mar. 3, 2021

Related U.S. Application Data
(60) Provisional application No. 62/985,092, filed on Mar. 4, 2020.

(51) Int. Cl. G01R 13/02; G01R 35/00

(52) U.S. Cl. CPC G01R 13/029; G01R 35/005; G01R 13/0272

(57) ABSTRACT

A test and measurement instrument having an input configured to acquire waveforms from a device under test, a memory configured to store the acquired waveforms, a user input configured to receive a selection, and one or more processors. The one or more processors can render on a display the acquired waveforms, receive the selection from the user input indicating a filter criterium, such as a region of interest in the displayed acquired waveforms, determine which waveforms of the acquired waveforms are within the region of interest, and render only waveforms associated with the region of interest on the display.

### PRIORITY

This disclosure claims benefit of U.S. Provisional Application No. 62/985,092, titled “METHOD OF IDENTIFYING ONE OR MORE ACQUISITIONS OF INTEREST OUT OF MANY USING SIMPLE VISUAL QUALIFICATION TOOLS,” filed on Mar. 4, 2020, which is incorporated herein by reference in its entirety.

### TECHNICAL FIELD

This disclosure is directed to systems and methods related to test and measurement systems, and in particular, to filtering acquired waveforms to view particular waveforms of interest.

### BACKGROUND

Conventional test and measurement instruments typically acquire and save a single record, or acquisition, at a time. The single acquisition is available for both simple visual investigation, as well as analytical investigation, using cursors, math, measurements, etc. When a user presses a “stop” button on the test and measurement instrument, only the most recent acquisition is available for analysis.

Some conventional test and measurement devices also offer additional acquisition modes, such as a Fast Frame acquisition, Segmented Memory acquisition, Ultra Segmentation acquisition, History, etc., that results in a multitude of acquisitions being saved in a memory of the device, rather than just one. The acquisitions are either displayed one at a time and the user must scroll through them or they are presented as overlaid on each other. To find the acquisition(s) of interest, a user must manually scroll through all the acquisitions, which can be in the thousands or even millions.

Examples of the disclosure address these and other deficiencies of the prior art.

### BRIEF DESCRIPTION OF THE DRAWINGS

Aspects, features and advantages of examples of the present disclosure will become apparent from the following description of examples in reference to the appended drawings in which:

FIG. 1 is a block diagram of a test and measurement instrument according to embodiments of the disclosure.

FIG. 2 is an illustration of an example of graphical user interface displayed on the test and measurement instrument according to examples of the disclosure.

FIG. 3 is an illustration of an example of a graphical user interface having received a user selection on the test and measurement instrument according to examples of the disclosure.

FIG. 4 is an illustration of an example of a graphical user interface that has filtered waveforms based on the user selection according to examples of the disclosure.

FIG. 5 is a flow chart of an operation of a test and measurement instrument according to examples of the disclosure.

### DESCRIPTION

Disclosed herein is a test and measurement instrument having an input configured to acquire a number of waveforms from a device under test, a memory configured to store the number of waveforms, a user input configured to receive a selection, and one or more processors. The one or more processors can render the number of waveforms after the number of waveforms have been acquired on a display, receive the selection from the user input indicating a filter criteria, such as a region of interest in the displayed number of waveforms, determine which waveforms of the numbers of waveforms are within the filter criteria, and render only waveforms associated with the region of interest on the display. The test and measurement instrument allows a user to quickly filter acquired waveforms without having to manually scroll through thousands or even millions of acquisitions.

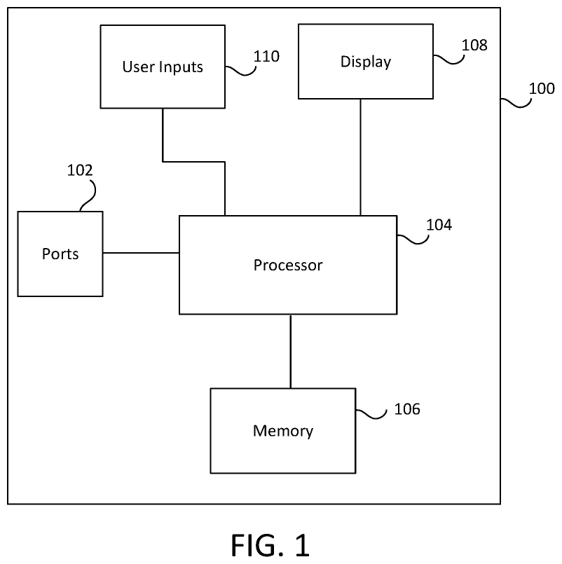

FIG. 1 is a block diagram of an example test and measurement instrument 100, such as an oscilloscope, for implementing embodiments of the disclosure disclosed herein. The test and measurement instrument 100 includes one or more ports 102 which may be any electrical signaling medium. Ports 102 may include receivers, transmitters, and/or transceivers. Each port 102 is a channel of the test and measurement instrument 100. The ports 102 are coupled with one or more processors 104 to process the signals and/or waveforms received at the ports 102 from one or more devices under test. Although only one processor 104 is shown in FIG. 1 for ease of illustration, as will be understood by one skilled in the art, multiple processors 104 of varying types may be used in combination, rather than a single processor 104.

The ports 102 can also be connected to a measurement unit in the test instrument 100, which is not depicted for ease of illustration. Such a measurement unit can include any component capable of measuring aspects (e.g., voltage, amperage, amplitude, etc.) of a signal received via ports 102. The test and measurement instrument may include additional hardware and/or processors, such as conditioning circuits, an analog to digital converter, and/or other circuitry to convert a received signal to a waveform for further analysis. The resulting waveform can then be stored in a memory 106, as well as displayed on a display 108.

The one or more processors 104 may be configured to execute instructions from memory 106 and may perform any methods and/or associated steps indicated by such instructions, such as displaying and modifying the graphical user interface (GUI) of embodiments of the disclosure. Memory 106 may be implemented as one or more of processor cache, random access memory (RAM), read only memory (ROM), solid state memory, hard disk drive(s), or any other memory type. Memory 106 acts as a medium for storing data, computer program products, and/or other instructions.

User inputs 110 are coupled to the one or more processors 104. User inputs 110 may include a keyboard, mouse, trackball, touchscreen, and/or any other controls employable by a user to interact with a GUI on the display 108. The display 108 may be a digital screen, a cathode ray tube based display, or any other monitor to display waveforms, measurements, and other data to a user. While the components of test and measurement instrument 100 are depicted as being integrated within test and measurement instrument 100, it will be appreciated by a person of ordinary skill in the art that any of these components can be external to test and measurement instrument 100 and can be coupled to test and measurement instrument 100 in any conventional manner (e.g., wired and/or wireless communication media and/or mechanisms). For example, in some embodiments, the display 108 may be remote from the test and measurement instrument 100.

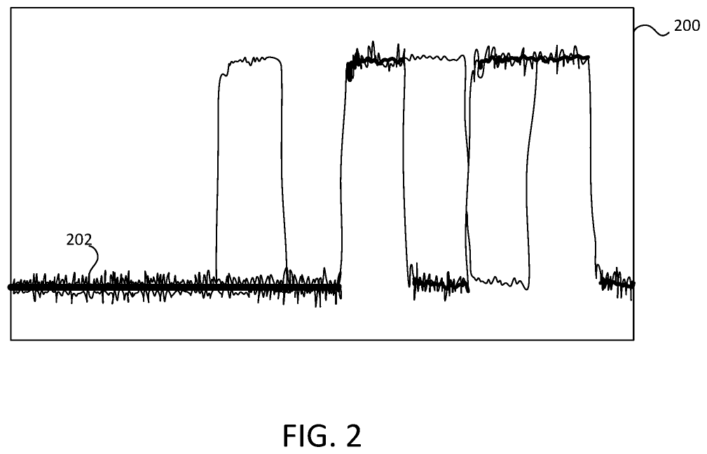

FIG. 2 illustrates an example of a GUI 200 which can display a number of acquisitions 202 acquired by the test and measurement instrument 100 and stored in the memory 106. The GUI 200 shows many acquisitions overlaid on top of each other and it is easy to tell at a glance the intermittent events, or other potentially interesting portions of acquired signals.

As discussed above, a conventional test and measurement instrument 100 displays all of the acquisitions at once and a user has to manually scroll or otherwise browse through the acquisitions to locate any signals of interest. In some embodiments, the GUI 200 can indicate the frequency of occurrence for the signal by, for example, color coding or otherwise distinguishing the waveforms.

For example, more frequent occurrences of the signal could be indicated by hotter colors, such as red or yellow, while less frequent events or occurrences could be indicated by cooler colors, such as green or blue. Alternatively, more frequent occurrences or events could be displayed in a bolder line, such as shown in FIG. 2, and less frequent events can be displayed with thinner lines.

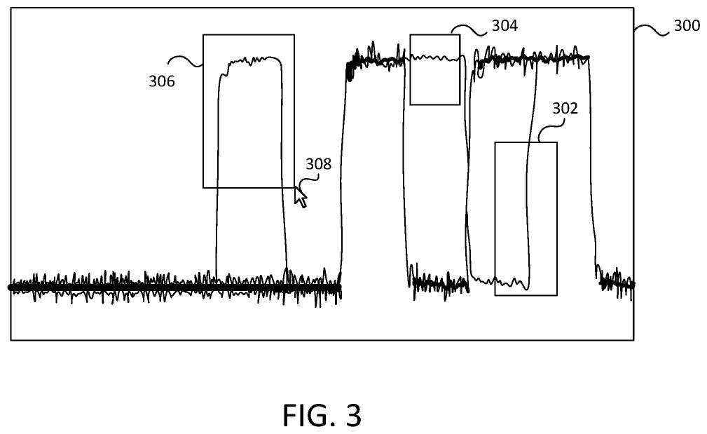

When the acquired waveforms are displayed, a user may determine that they want to investigate or further view only certain waveforms. FIG. 3 illustrates a GUI 300 showing a selection by a user to waveforms or areas of interest.

In GUI 300, the acquired waveforms are all displayed to a user. As seen in FIG. 3, a user has selected three regions of interest 302, 304, and 306. The regions of interest 302, 304, and 306 can be selected through the user inputs 110, such as by using the cursor 308 displayed on the GUI to draw a selected region of interest. While the regions of interest 302, 304, and 306 are displayed as boxes, examples of the disclosure are not limited to this configuration. The regions of interest selected by a user through the user inputs 110 may be any shape, such as, but not limited to, circles, triangles, and freeform shapes. Further, region of interest, or criteria, may not be a shape, but may be a set characteristic of the waveforms, such as waveforms having a particular amplitude, frequency, pulse width, etc.

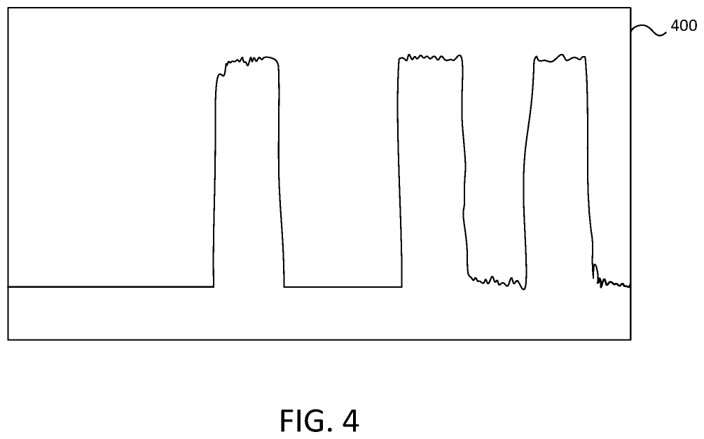

Once the regions of interest 302, 304, and 306, in this example, have been identified, then the one or more processors 104 can determine which waveforms of the acquired waveforms fall within the regions of interest 302, 304, and 306. Once the waveforms have been identified, then, as illustrated by the GUI 400 in FIG. 4, only the waveforms that fall within the regions of interest 302, 304, and 306 are displayed on the display 108.

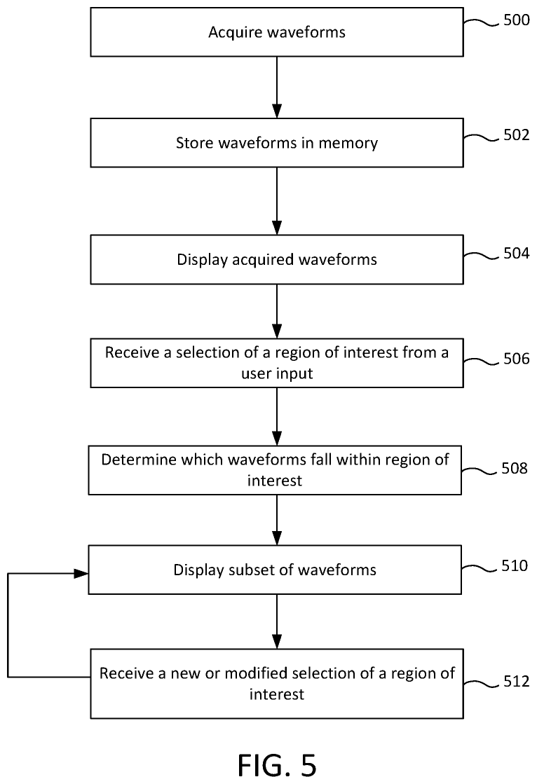

FIG. 5 illustrates an example operation of a test and measurement instrument 100 according to examples of the disclosure. In operation 500, a number of waveforms are acquired from a device under test during operation of the test and measurement instrument 100. The number of acquired waveforms may be at least one, but embodiments of the disclosure may be particularly useful when the number of acquired waveforms is a large number of waveforms, such as, but not limited to, hundreds, thousands, or millions of waveforms. In operation 502, the acquired waveforms are stored in a memory 106. Post-acquisition of the waveforms, the one or more processors 104 can cause a GUI to be displayed on the display 108 showing or illustrating all of the acquired waveforms overlaid on each other in operation 504.

In operation 506, a selection indicating one or more regions of interest can be received by the user inputs 110 to indicate a region of interest on the GUI displayed. In operation 508, the one or more processors can determine which waveforms, if any, of the acquired waveforms fall within the region of interest selected. The region of interest can be selected by drawing a shape over waveforms or portions of waveforms that a user wants to include. That is, the region of interest indicates which points of interest are to be included. In other examples, the region of interest can be drawn such that anything within the shape is not included. That is, the region of interest is outside the shape and the interior of the shape is marked or indicated as not to be included.

In some examples, multiple types of regions of interest can be included. For example, a user may select that they are interested in any waveform that falls within any region of interest selected. In other examples, a user may select that they are interested only in waveforms that are within every region of interest. That is, different combinations of types of regions of interest may be selected by a user. The criteria for the regions of interest may be, for example, “must hit,” “must not hit,” and/or “do not care.” That is, the one or more processors 104 can filter the acquired waveforms based on the regions of interest selected by the user and remove any waveforms from the GUI that do not fall within the criteria set by the user in the regions of interest.

In some examples, waveforms from multiple ports 102 may be acquired and displayed. Each of the waveforms acquired for a particular port may be, for example, overlaid on each other, while multiple windows may be provided, each window showing overlaid waveforms for a particular port. The filter criteria can be based on the waveforms in multiple windows. For example, a signal from a device under test may be received at one port, while a temperature signal is received from another port. A user can select criteria directed to both signals to filter the acquired waveforms. For example, the user may select a region of interest, or other filter criteria related to the signal from the device under test, but may also specify that it is only interested in that data when the temperature signal is violating a specified threshold.

Once filtered, the one or more processors 104 can perform any number of operations on the filtered waveforms, such as various measurements. Further, the criteria for the regions of interest may be suggested to a user, such as trigger criteria that were previously set by the user during the acquisition.

In operation 510, the waveforms that meet the criteria selected by a user are displayed. In operation 512, a new selection or modification of a current region of interest may be received through the user inputs 110. The one or more processors 104 then return to operation 510 and filter the acquired waveforms in accordance with the new regions of interest. That is, as a region of interest is modified, moved, added, or deleted, acquisition waveforms displayed on the GUI will automatically appear and/or disappear, depending on the regions of interest, allowing a user to quickly, simply, and intuitively find specific acquisition that are of interest to the user, rather than having to manually investigate the thousands or even millions of acquisitions.

Aspects of the disclosure may operate on particularly created hardware, firmware, digital signal processors, or on a specially programmed computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a computer readable storage medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or computer-readable storage media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the technologies disclosed herein are provided below. An embodiment of the technologies may include any one or more, and any combination of, the examples described below.

Example 1 a test and measurement instrument, comprising an input configured to acquire waveforms from a device under test; a memory configured to store the acquired waveforms; a user input configured to receive a selection; and one or more processors configured to render the acquired waveforms on a display, receive the selection from the user input indicating a region of interest in the displayed acquired waveforms, determine which waveforms of the acquired waveforms are within the region of interest, and render only waveforms associated with the region of interest on the display.

Example 2 is the test and measurement instrument of example 1, wherein the selection includes multiple regions of interest, and the one or more processors are further configured to determine which waveforms of the acquired waveforms are within at least one of the regions of interest and render only waveforms associated with at least one of the regions of interest on the display.

Example 3 is the test and measurement instrument of example 2, wherein the one or more processors are further configured to determine which waveforms of the acquired waveforms are within all the regions of interest and render only waveforms associated with all the regions of interest on the display.

Example 4 is the test and measurement instrument of any one of examples 1-3, wherein the selection is a first selection and the one or more processors are further configured to receive a second selection from the user input indicating a second region of interest in the displayed acquired waveforms, determine which waveforms of the acquired waveforms are within the second region of interest, and render only waveforms associated with the second region of interest on the display.

Example 5 is the test and measurement instrument of any one of examples 1-3, wherein the selection is a first selection and the one or more processors are further configured to receive a second selection from the user input indicating a modification to the region of interest, determine which waveforms of the acquired waveforms are within the modified region of interest, and render only waveforms associated with the modified region of interest on the display.

Example 6 is the test and measurement instrument of example 5, wherein the modification is adding a second region of interest, deleting the region of interest, or changing a characteristic of the region of interest.

Example 7 is the test and measurement instrument of any one of examples 1-6, wherein the selection is a waveform characteristic, and the one or more processors determine the region of interest based on the waveform characteristic.

Example 8 is a method for selectively displaying acquired waveforms, comprising displaying a plurality of acquired waveforms from a memory on a display; receiving a filter criteria from a user input; filtering the acquired waveforms from the memory based on the filter criteria to determine filtered waveforms; and causing the display to update and display only the filtered waveforms from the acquired waveforms.

Example 9 is the method of example 8, wherein the filter criteria includes multiple regions of interest, and the filtered waveforms include waveforms from the acquired waveforms that are within at least one of the regions of interest.

Example 10 is the method of example 9, wherein the filtered waveforms include waveforms from the acquired waveforms that are within all the regions of interest.

Example 11 is the method of either one of examples 8 or 9, wherein the filter criteria is a first filter criteria and the method further includes receiving a second filter criteria from the user input; and filtering the acquired waveforms from the memory based on the second filter criteria to determine filtered waveforms.

Example 12 is the method of any one of examples 8-11, further comprising receiving a modification of the filter criteria from the user input; and filtering the acquired waveforms from the memory based on the modified filter criteria to determine filtered waveforms.

Example 13 is the method of example 12, wherein the modification is adding a second filter criteria, deleting the filter criteria, or changing a characteristic of the filter criteria.

Example 14 is the method of any one of examples 8-13, wherein the filter criteria comprises a waveform characteristic.

Example 15 is one or more non-transitory computer-readable storage media comprising instructions, which, when executed by one or more processors of a test and measurement instrument, cause the test and measurement instrument to display a plurality of acquired waveforms from a memory; receive a filter criteria from a user input; filter the acquired waveforms from the memory based on the filter criteria to determine filtered waveforms; and update and display only the filtered waveforms from the acquired waveforms.

Example 16 is the one or more non-transitory computer-readable storage media of example 15, wherein the filter criteria includes multiple regions of interest, and the filtered waveforms include waveforms from the acquired waveforms that are within at least one of the regions of interest.

Example 17 is the one or more non-transitory computer-readable storage media of example 16, wherein the filtered waveforms include waveforms from the acquired waveforms that are within all the regions of interest.

Example 18 is the one or more non-transitory computer-readable storage media of any one of examples 15-17, further comprising instructions to cause the test and measurement instrument to receive a modification of the filter criteria from the user input; and filter the acquired waveforms from the memory based on the modified filter criteria to determine filtered waveforms.

Example 19 is the one or more non-transitory computer-readable storage media of example 18, wherein the modification is adding a second filter criteria, deleting the filter criteria, or changing a characteristic of the filter criteria.

Example 20 is the one or more non-transitory computer-readable storage media of any one of examples 15-19, wherein the filter criteria comprises a waveform characteristic.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the disclosure have been illustrated and described for purposes of illustration, it will be understood that various modifications may be made without departing from the spirit and scope of the disclosure. Accordingly, the disclosure should not be limited except as by the appended claims.

We claim:

1. A test and measurement instrument, comprising:
an input configured to acquire waveforms from a device under test;
a memory configured to store the acquired waveforms;
a user input configured to receive a selection; and
one or more processors configured to:
render the acquired waveforms on a display,
receive the selection from the user input indicating a region of interest in the displayed acquired waveforms,
determine which waveforms of the acquired waveforms are within the region of interest, and
render only waveforms associated with the region of interest on the display.

2. The test and measurement instrument of claim 1, wherein the selection includes multiple regions of interest, and the one or more processors are further configured to determine which waveforms of the acquired waveforms are within at least one of the regions of interest and render only waveforms associated with at least one of the regions of interest on the display.

3. The test and measurement instrument of claim 2, wherein the one or more processors are further configured to determine which waveforms of the acquired waveforms are within all the regions of interest and render only waveforms associated with all the regions of interest on the display.

4. The test and measurement instrument of claim 1, wherein the selection is a first selection and the one or more processors are further configured to:
receive a second selection from the user input indicating a second region of interest in the displayed acquired waveforms,
determine which waveforms of the acquired waveforms are within the second region of interest, and
render only waveforms associated with the second region of interest on the display.

5. The test and measurement instrument of claim 1, wherein the selection is a first selection and the one or more processors are further configured to:
receive a second selection from the user input indicating a modification to the region of interest,
determine which waveforms of the acquired waveforms are within the modified region of interest, and
render only waveforms associated with the modified region of interest on the display.

6. The test and measurement instrument of claim 5, wherein the modification is adding a second region of interest, deleting the region of interest, or changing a characteristic of the region of interest.

7. The test and measurement instrument of claim 1, wherein the selection is a waveform characteristic, and the one or more processors determine the region of interest based on the waveform characteristic.

8. A method for selectively displaying acquired waveforms, comprising:
displaying a plurality of acquired waveforms from a memory on a display;
receiving a filter criteria from a user input;
filtering the acquired waveforms from the memory based on the filter criteria to determine filtered waveforms; and
causing the display to update and display only the filtered waveforms from the acquired waveforms.

9. The method of claim 8, wherein the filter criteria includes multiple regions of interest, and the filtered waveforms include waveforms from the acquired waveforms that are within at least one of the regions of interest.

10. The method of claim 9, wherein the filtered waveforms include waveforms from the acquired waveforms that are within all the regions of interest.

11. The method of claim 8, wherein the filter criteria is a first filter criteria and the method further includes:
receiving a second filter criteria from the user input; and
filtering the acquired waveforms from the memory based on the second filter criteria to determine filtered waveforms.

12. The method of claim 8, further comprising:
receiving a modification of the filter criteria from the user input; and
filtering the acquired waveforms from the memory based on the modified filter criteria to determine filtered waveforms.

13. The method of claim 12, wherein the modification is adding a second filter criteria, deleting the filter criteria, or changing a characteristic of the filter criteria.

14. The method of claim 8, wherein the filter criteria comprises a waveform characteristic.

15. One or more non-transitory computer-readable storage media comprising instructions, which, when executed by one or more processors of a test and measurement instrument, cause the test and measurement instrument to:
display a plurality of acquired waveforms from a memory;
receive a filter criteria from a user input;
filter the acquired waveforms from the memory based on the filter criteria to determine filtered waveforms; and
update and display only the filtered waveforms from the acquired waveforms.

16. The one or more non-transitory computer-readable storage media of claim 15, wherein the filter criteria includes multiple regions of interest, and the filtered waveforms include waveforms from the acquired waveforms that are within at least one of the regions of interest.

17. The one or more non-transitory computer-readable storage media of claim 16, wherein the filtered waveforms include waveforms from the acquired waveforms that are within all the regions of interest.

18. The one or more non-transitory computer-readable storage media of claim 15, further comprising instructions to cause the test and measurement instrument to:
receive a modification of the filter criteria from the user input; and
filter the acquired waveforms from the memory based on the modified filter criteria to determine filtered waveforms.

19. The one or more non-transitory computer-readable storage media of claim 18, wherein the modification is adding a second filter criteria, deleting the filter criteria, or changing a characteristic of the filter criteria.

20. The one or more non-transitory computer-readable storage media of claim 15, wherein the filter criteria comprises a waveform characteristic.
